(19) United States
(12) Patent Application Publication
(10) Pub. No.: US 2011/0003466 A1
(43) Pub. Date: Jan. 6, 2011

(54) METHODS OF FORMING A MULTI-DOPED JUNCTION WITH POROUS SILICON

(75) Inventors: Giuseppe Scardera, Sunnyvale, CA (US); Homer Antoniadis, Montalto, CA (US); Nick Cravalho, Palo Alto, CA (US); Maxim Kelman, Mountain View, CA (US); Elena Rogojina, Los Altos, CA (US); Karel Vanheusden, Los Altos, CA (US)

Correspondence Address: Foley & Lardner LLP, Suite 500, 3000 K STREET NW, Washington, DC, 20007, US

(73) Assignee: Innovalight, Inc.

(21) Appl. No.: 12/794,188

(22) Filed: Jun. 4, 2010

Related U.S. Application Data
(63) Continuation-in-part of application No. 12/692,878, filed on Jan. 25, 2010.
Application No. 12/692,878 is a continuation-in-part of application No. 12/656,710, filed on Feb. 12, 2010.
(60) Provisional application No. 61/222,628, filed on Jul. 2, 2009.

(51) Int. Cl. H01L 21/22

(52) U.S. Cl. 438/565; 257/E21.135

(57) ABSTRACT

A method of forming a multi-doped junction on a substrate is disclosed. The method includes providing the substrate doped with boron atoms, the substrate comprising a front crystalline substrate surface; and forming a mask on the front crystalline substrate surface, the mask comprising exposed mask areas and non-exposed mask areas. The method also includes exposing the mask to an etchant, wherein porous silicon is formed on the front crystalline substrate surface defined by the exposed mask areas; and removing the mask. The method further includes exposing the substrate to a dopant source in a diffusion furnace with a deposition ambient, the deposition ambient comprising POCl₃ gas, at a first temperature and for a first time period, wherein a PSG layer is formed on the front substrate surface; and heating the substrate in a drive-in ambient to a second temperature and for a second time period. Wherein a first diffused region with a first sheet resistance is formed under the porous silicon and a second diffused region with a second sheet resistance is formed under the front crystalline substrate surface without the porous silicon, and wherein the first sheet resistance is substantially smaller than the second sheet resistance.

### CROSS-REFERENCE TO RELATED APPLICATIONS

This application claims the benefit of U.S. Pat. App. No. 61/222,628 filed Jul. 2, 2009, entitled Methods of Using A Silicon Particle Fluid To Control In Situ A Set Of Dopant Diffusion Profiles, U.S. patent application Ser. No. 12/692,878, filed Jan. 25, 2010, entitled Methods Of Forming A Dual-Doped Emitter On A Substrate With An Inline Diffusion Apparatus, and, U.S. patent application Ser. No. 12/656,710, filed Feb. 12, 2010, entitled Methods of Forming a Multi-Doped Junction with Silicon-Containing Particles, the entire disclosures of which is incorporated by reference.

### FIELD OF DISCLOSURE

This disclosure relates in general to p-n junctions and in particular to methods of forming a multi-doped junction with porous silicon.

### BACKGROUND

A solar cell converts solar energy directly to DC electric energy. Generally configured as a photodiode, a solar cell permits light to penetrate into the vicinity of metal contacts such that a generated charge carrier (electrons or holes (a lack of electrons)) may be extracted as current. And like most other diodes, photodiodes are formed by combining p-type and n-type semiconductors to form a junction.

Electrons on the p-type side of the junction within the electric field (or built-in potential) may then be attracted to the n-type region (usually doped with phosphorous) and repelled from the p-type region (usually doped with boron), whereas holes within the electric field on the n-type side of the junction may then be attracted to the p-type region and repelled from the n-type region. Generally, the n-type region and/or the p-type region can each respectively be comprised of varying levels of relative dopant concentration, often shown as n−, n+, n++, p−, p+, p++, etc. The built-in potential and thus magnitude of electric field generally depend on the level of doping between two adjacent layers.

Substantially affecting solar cell performance, carrier lifetime (recombination lifetime) is defined as the average time it takes an excess minority carrier (non-dominant current carrier in a semiconductor region) to recombine and thus become unavailable to conduct an electrical current. Likewise, diffusion length is the average distance that a charge carrier travels before it recombines. In general, although increasing dopant concentration improves conductivity, it also tends to increase recombination. Consequently, the shorter the recombination lifetime or recombination length, the closer the metal region must be to where the charge carrier was generated.

Most solar cells are generally manufactured on a silicon substrate doped with a first dopant (commonly boron) forming an absorber region, upon which a second counter dopant (commonly phosphorous), is diffused forming the emitter region, in order to complete the p-n junction. After the addition of passivation and antireflection coatings, metal contacts (fingers and busbar on the emitter and pads on the back of the absorber) may be added in order to extract generated charge. Emitter dopant concentration, in particular, must be optimized for both carrier collection and for contact with the metal electrodes.

Referring now to FIG. 1, a simplified diagram of a traditional front-contact solar cell is shown. In a common configuration, a phosphorous-doped (n-type) emitter region 108 is first formed on a boron-doped silicon substrate 110 (p-type), although a configuration with a boron-doped emitter region on a phosphorus-doped silicon substrate may also be used.

Prior to the deposition of silicon nitride (SiNₓ) layer 104 on the front of the substrate, residual surface glass (PSG) formed on the substrate surface during the POCl₃ deposition process may be removed by exposing the doped silicon substrate to an etchant, such as hydrofluoric acid (HF). The set of metal contacts, comprising front-metal contact 102 and back surface field (BSF)/back metal contact 116, are then sequentially formed on and subsequently fired into doped silicon substrate 110.

The front metal contact 102 is commonly formed by depositing an Ag (silver) paste, comprising Ag powder (about 70 to about 80 wt % (weight percent)), lead borosilicate glass (frit) PbO—B₂O₃—SiO₂ (about 1 to about 10 wt %), and organic components (about 15 to about 30 wt %). After deposition the paste is dried at a low temperature to remove organic solvents and fired at high temperatures to form the conductive metal layer and to enable the silicon-metal contact.

BSF/back metal contact 116 is generally formed from aluminum (in the case of a p-type substrate) and is configured to create an electrical field that repels and thus minimizes the impact of minority carrier rear surface recombination. In addition, Ag pads [not shown] are generally applied onto BSF/back metal contract 116 in order to facilitate soldering for interconnection into modules.

However, a low concentration of (substitutional) dopant atoms within an emitter region generally results in both low recombination (thus higher solar cell efficiencies) and poor electrical contact to metal electrodes. Conversely, a high concentration of (substitutional) dopant atoms results in both high recombination (thus reducing solar cell efficiency) and low resistance ohmic contacts to metal electrodes. In order to reduce manufacturing costs, single dopant diffusion is often used to form an emitter, with a doping concentration selected as a compromise between low recombination and low resistance ohmic contact. Consequently, potential solar cell efficiency (the percentage of sunlight that is converted to electricity) is limited.

In view of the foregoing, there is a desire to provide methods of optimizing the dopant concentration in a solar cell.

### SUMMARY

The invention relates, in one embodiment, to a method of forming a multi-doped junction on a substrate. The method includes providing the substrate doped with boron atoms, the substrate comprising a front crystalline substrate surface; and forming a mask on the front crystalline substrate surface, the mask comprising exposed mask areas and non-exposed mask areas. The method also includes exposing the mask to an etchant, wherein porous silicon is formed on the front crystalline substrate surface defined by the exposed mask areas; and removing the mask. The method further includes exposing the substrate to a dopant source in a diffusion furnace with a deposition ambient, the deposition ambient comprising POCl₃ gas, at a first temperature and for a first time period, wherein a PSG layer is formed on the front substrate surface; and heating the substrate in a drive-in ambient to a second temperature and for a second time period. Wherein a first diffused region with a first sheet resistance is formed under the porous silicon and a second diffused region with a second sheet resistance is formed under the front crystalline substrate surface without the porous silicon, and wherein the first sheet resistance is substantially smaller than the second sheet resistance.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows a simplified diagram of a traditional front-contact solar cell;

FIG. 2 shows a simplified diagram of a front-contact solar cell with a porous silicon region, in accordance with the invention;

FIGS. 3A-B show a set of simplified figures comparing various optical and electrical characteristics for three sets of 1″×1″ p-type silicon substrates, in accordance with the invention;

FIG. 4 shows FTIR spectra for two double-sided polished mono-crystalline silicon substrates, a first with a porous silicon layer and a second without any porous silicon, in accordance with the invention;

FIGS. 5A-G show a simplified method for forming a multi-doped junction on a substrate with porous silicon with a positive pattern mask, in accordance with the invention; and,

FIGS. 6A-H show a simplified method for forming a multi-doped junction on a substrate with porous silicon with a negative pattern mask, in accordance with the invention.

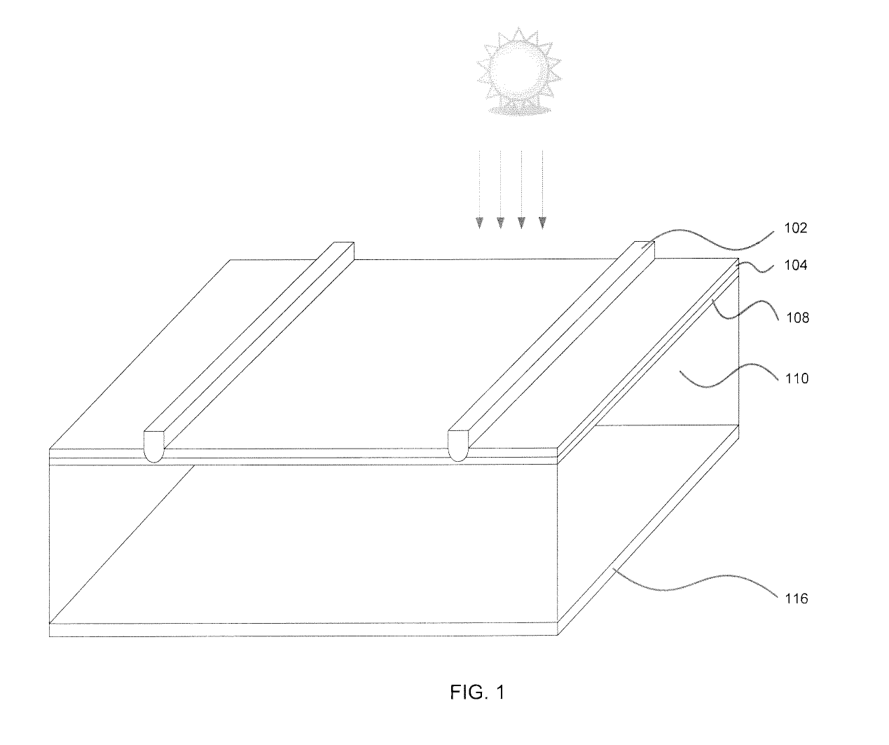

### DETAILED DESCRIPTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

As previously described, the single dopant diffusion generally used to form an emitter is a compromise between low recombination and a low resistance ohmic contact. Consequently, potential solar cell efficiency (the percentage of sunlight that is converted to electricity) is limited.

While not wishing to be bound by theory, the inventors believe that porous silicon may be used to form a selective emitter. In general, porous silicon is a form of silicon with nano-scale voids, rendering a large silicon surface to volume ratio (in the order of 500 m²/cm³). Porosity is generally defined as the fraction of void within the porous silicon

In one configuration, in order to diffuse phosphorous into a boron doped silicon substrate in a quartz tube furnace, POCl₃ (phosphorus oxychloride) is used. The reaction is typically:

4POCl₃₍₂₎+3O₂₍₂₎→2P₂O₅₍₂₎+6Cl₂₍₂₎ [Equation 1A]

2P₂O₅₍₂₎5Si₍₂₎→5SiO₂₍₂₎4P₍₂₎ [Equation 1B]

Si+O₂→SiO₂ [Equation 2]

The typical gases involved in a POCl₃ diffusion process include: an ambient nitrogen gas (main N₂ gas), a carrier nitrogen gas (carrier N₂ gas) which is flowed through a bubbler filled with liquid POCl₃, a reactive oxygen gas (reactive O₂ gas) configured to react with the vaporized POCl₃ to form the deposition (processing) gas, and optionally a main oxygen gas (main O₂ gas) configured to later form an oxide layer.

In general, a silicon substrate is first placed in a heated tube furnace with a nitrogen gas ambient (main N₂ gas). The deposition gas (POCl₃ vapor) is then flowed into the tube furnace, heated to a deposition temperature, and exposed to reactive O₂ (oxygen) gas to form P₂O₅ (phosphorus pentoxide) on the silicon substrate, as well as Cl₂ (chlorine) gas that interacts with and removes metal impurities in the silicon substrate. P₂O₅ in turn reacts with the silicon substrate to form SiO₂, and free P atoms. The simultaneous oxidation of the silicon wafer during the deposition results in the formation of a SiO₂.P₂O₅ layer (PSG or phosphosilicate glass).

An additional drive-in step (free of any POCl₃ flow) is typically employed using the deposition temperature or a higher temperature in order to enable the free phosphorous atoms to diffuse further into the silicon substrate and substitutionally replace silicon atoms in the lattice in order to be available for charge carrier generation. During this step, ambient gas which may comprise of main N₂ gas and/or main O₂ gas is flowed into the tube furnace. The use of oxygen would result in the formation of an oxide layer at the silicon wafer surface. Such an oxide layer attenuates the diffusion of P atoms from the PSG layer into the silicon substrate allowing for more control over the resultant diffusion profiles. In general, for a given temperature phosphorous diffuses slower in SiO₂ than in silicon.

Another approach to phosphorus doping of silicon wafers is a spray-on technique whereby a phosphoric acid (H₃PO₄) mixture (usually mixed with water or an alcohol like ethanol or methanol) is sprayed onto the wafer and then subjected to a thermal treatment. The diffusion of phosphorus into a silicon wafer using phosphoric acid as a dopant source occurs via the following reaction:

2H₃PO₄→P₂O₅+3H₂O[Equation 3A]

2P₂O₅+3Si→3SiO₂+4P [Equation 3B]

The first step involves the dehydration of phosphoric acid which produces phosphorus pentoxide (P₂O₅) on the silicon surface which in turn acts as the phosphorus source. P₂O₅ in turn reacts with the silicon substrate to form SiO₂, and free P atoms. An example of this process is further disclosed in U.S. patent application Ser. No. 12/692,878, filed Jan. 25, 2010, the entire disclosure of which is incorporated by reference.

Likewise, boron may be deposited on a phosphorus doped silicon substrate using BBr₃ (boron tri-bromide). The reaction is typically:

4BBr₃₍₂₎+3O₂₍₂₎→2B₂O₃₍₂₎+6Br₃₍₂₎ [Equation 4A]

2B₂O₃₍₂₎+3Si₂→4B₍₂₎+3SiO₂₍₂₎ [Equation 4B]

Si+O₂=SiO₂ [Equation 2]

In general, a silicon substrate is first placed in a heated tube furnace which has a nitrogen gas (main N₂ gas), a carrier nitrogen gas (carrier N₂) which is flowed through a bubbler filled with liquid BBr₃, a reactive oxygen gas (reactive O₂ gas) configured to react with the vaporized BBr₃ to form B₂O₃ (boric oxide) on the silicon substrate, and optionally a main oxygen gas (main O₂ gas) configured to later form an oxide layer.

B₂O₃ in turn reacts with the silicon substrate to form SiO₂, and free B atoms. The simultaneous oxidation of the silicon wafer during the deposition results in the formation of a SiO₂.B₂O₃ layer (BSG or boro-silicate glass)

An additional drive-in step (free of any BBr₃ flow) is typically employed using the deposition temperature or a higher temperature in order to enable the free boron atoms to diffuse further into the silicon substrate and substitutionally replace silicon atoms in the lattice in order to be available for charge carrier generation. During this step, ambient gas which may comprise of nitrogen (main N₂) and/or oxygen (main O₂) is flowed into the tube furnace. The use of oxygen would result in the formation of an oxide layer at the silicon wafer surface. Such an oxide layer attenuates the diffusion of boron atoms from the B₂O₃ layer into the silicon substrate allowing for more control over the resultant diffusion profiles. In general, for a given temperature boron diffuses slower in SiO₂ than in silicon. In some cases a pre-deposition oxide layer may be grown onto the silicon wafer to allow for better diffusion uniformity.

In the case of a selective emitter, a lightly doped region with sheet resistance of between about 70 Ohm/sq to about 140 Ohm/sq is optimal, while a heavily doped region (of the same dopant type) with a sheet resistance of between about 20 Ohm/sq to about 70 Ohm/sq is optimal.

In an advantageous manner, a substrate with porous silicon regions exposed to a deposition ambient (such as POCl₃, H3PO₄, or BBr₃) may allow a larger volume of surface PSG (or BSG in the case of BBr₃) to be locally deposited, which in turn, allows for a larger amount of the dopant to be locally driven into the underlying wafer. Consequently, a set of heavily doped regions (under areas with porous silicon) and a set of lightly doped regions (under areas without porous silicon) may both be formed in the dopant diffusion ambient.

For example, in one configuration, a patterned positive mask is first deposited on the substrate, with exposed areas of the mask corresponding to subsequent metal contact regions. The substrate is subjected to a set of etchants (i.e., HF and HNO₃ mixture, etc.), subsequently etching into the uncovered areas of the substrate to create porous silicon regions. After removing the mask, the p-type silicon substrate is placed in a heated tube furnace and exposed to the deposition gas (POCl₃ vapor) and O₂ (oxygen) gas to form P₂O₅ (phosphorus pentoxide) on the substrate surface and on the porous silicon regions following the reactions of Equation 1A-1B.

In another configuration, the substrate is exposed to a set of etchants (i.e. HF and HNO₃ mixture, etc.), subsequently etching into the substrate to create porous silicon regions. A patterned negative mask is subsequently deposited on the substrate, with covered areas of the mask corresponding to subsequent metal contact regions. The substrate is subjected to a set of etchants (KOH, HF and HNO₃ mixture, etc.) etching back the porous silicon regions in the exposed areas of the mask. After removing the mask, the p-type silicon substrate is placed in a heated tube furnace and exposed to the deposition gas (POCl₃ vapor) and O₂ (oxygen) gas to form P₂O₅ (phosphorus pentoxide) on the substrate surface and on the porous silicon regions following the reactions of Equations 1A-B.

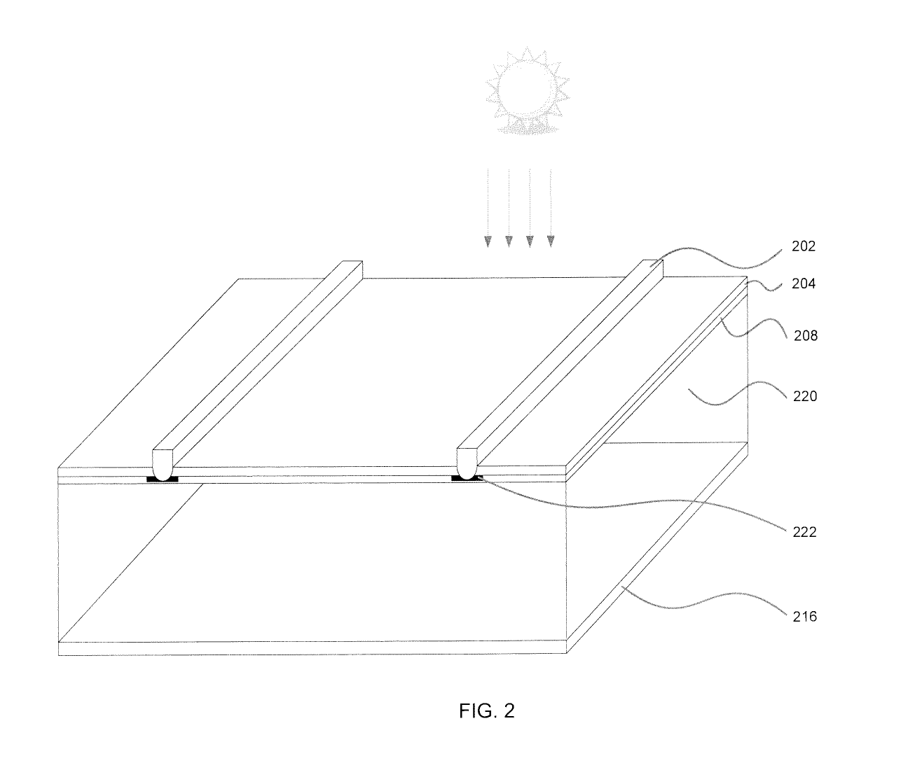

Referring now to FIG. 2, a simplified diagram is shown of a front-contact solar cell with a porous silicon region, in accordance with the invention. In an advantageous manner, a porous silicon region 222 formed on a boron-doped silicon substrate 220 (prior to the formation of phosphorous-doped emitter region 208) enables the formation of an optimal silicon metal contact. In one configuration, a masking layer is deposited on substrate 220 with openings corresponding to later formed front metal contact 202. The masked substrate is then exposed to a mixture of HF and HNO₃. The mask is subsequently removed and the substrate is subjected to a POCl₃ diffusion process. In addition, prior to the deposition of silicon nitride (SiNₓ) layer 204 on the front of the substrate, residual surface glass (PSG) formed on the substrate surface during the POCl₃ deposition process is commonly removed by exposing the doped silicon substrate to hydrofluoric acid (HF). The set of metal contacts, comprising front-metal contact 202 and back surface field (BSF)/back metal contact 216, are then sequentially formed on and subsequently fired into doped silicon substrate 220.

### Experiment 1

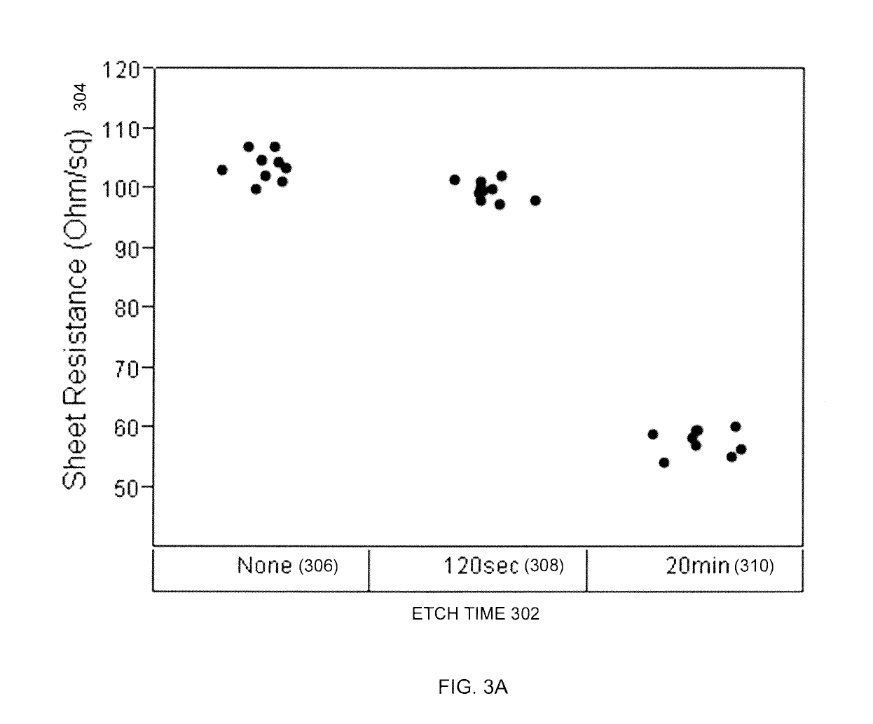

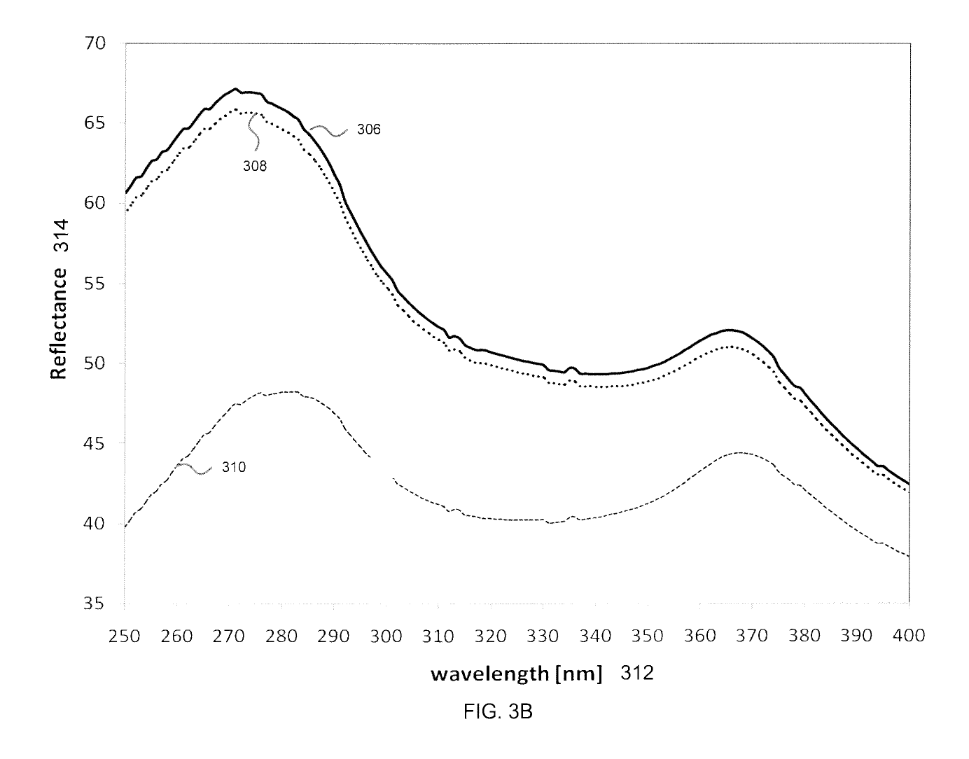

Referring now to FIGS. 3A-B, a set of simplified figures comparing various optical and electrical characteristics for three sets of 1″×1″ p-type silicon substrates, in accordance with the invention. Porous silicon with different porosity (silicon surface area) was formed on substrate subsets 308 and 310 by varying the etch time (120 seconds for substrate subset 308 and 20 minutes for substrate subset 310). Porous silicon was not formed on substrate subset 306.

The substrates were first cleaned with a mixture of hydrofluoric acid (HF) and hydrochloric acid (HCl), followed by a DI water rinsing step. All substrates were then dried using N₂. Porous silicon was formed on substrate subsets 308 and 310 by immersion in an HF and HNO₃ mixture, although other etchants and etchant techniques may also be used.

All substrates were then exposed to a dopant source in a diffusion furnace with an atmosphere of POCl₃, N₂, and O₂. All the substrates subsets had an initial deposition temperature of about 800° C. for 20 minutes. The inventors believe the initial deposition temperature may preferably be between about 725° C. and about 850° C., more preferably between about 750° C. and about 825° C., and most preferably about 800° C. The initial deposition time period may preferably be between about 10 minutes and about 35 minutes, more preferably between about 15 minutes and about 30 minutes, and most preferably about 20 minutes. Furthermore, a 1:1 ratio of nitrogen (carrier N₂ gas) to oxygen (reactive O₂ gas) during deposition was employed. The inventors believe that carrier N₂ gas to reactive O₂ ratios of between 1:1 and 1.5:1 during the deposition step to be preferable.

The initial deposition was followed by a drive-in step with drive-in temperature of about 900° C. for about 25 minutes in an N₂ ambient. The residual PSG glass layers on the substrate surface and the porous silicon were subsequently removed by a buffered oxide etch (BOE) cleaning step for about 5 minutes.

FIG. 3A shows the sheet resistance for the three silicon substrate subsets. The process resulted in an average sheet resistance of 104.1 ohm/sq for substrate subset 306 (without porous silicon), an average sheet resistance of 100.2 ohm/sq for substrate subset 308 (with porous silicon created using a 120 second etch), and an average sheet resistance of 58.3 ohm/sq for substrate subset 310 (with porous silicon created using a 20 minute etch).

Consequently, the longer etch period of substrate subset 310 (corresponding to a greater amount of silicon surface area when compared to the un-etched silicon substrate surface) creates a substantially lower sheet resistance and thus a higher diffused phosphorous concentration.

The inventors believe the drive-in temperature may be preferably between about 850° C. and about 1050° C., more preferably between about 860° C. and about 950° C., and most preferably about 875° C. The drive-in time period may be preferably between about 10 minutes and about 60 minutes, more preferably between about 15 minutes and about 30 minutes, and most preferably about 25 minutes.

FIG. 3B shows the reflectance, in the ultraviolet range, for the three silicon substrate subsets prior to being exposed to a dopant source in a diffusion furnace, in accordance with the invention. In general, reflectivity is dependent on refractive index of porous silicon and the porosity of the porous silicon region, with more porous regions corresponding to lower reflectance (higher absorption). Wavelength 312 is shown on the horizontal axis, while reflectance 314 in percentage is shown along the vertical axis. Spectrum 306 shows peaks at approximately 275 nm and 365 nm, which correspond to direct electronic band transitions in silicon. As can be seen, silicon substrate subsets 306 (without porous silicon) and 308 (with porous silicon created at a 120 second etch) show comparable reflectance spectra. Spectrum 310 (with porous silicon created at a 20 minute etch) shows an overall lower reflectance and the lower wavelength peak has shifted to a longer wavelength of approximately 280 nm. Both these trends are consistent with an increase in porosity (and substantially more silicon surface area) as demonstrated by Theiβ. [W. Theiβ, “Optical properties of porous silicon”, Surface Science Reports 29 (1997) 91-192.]

### Experiment 2

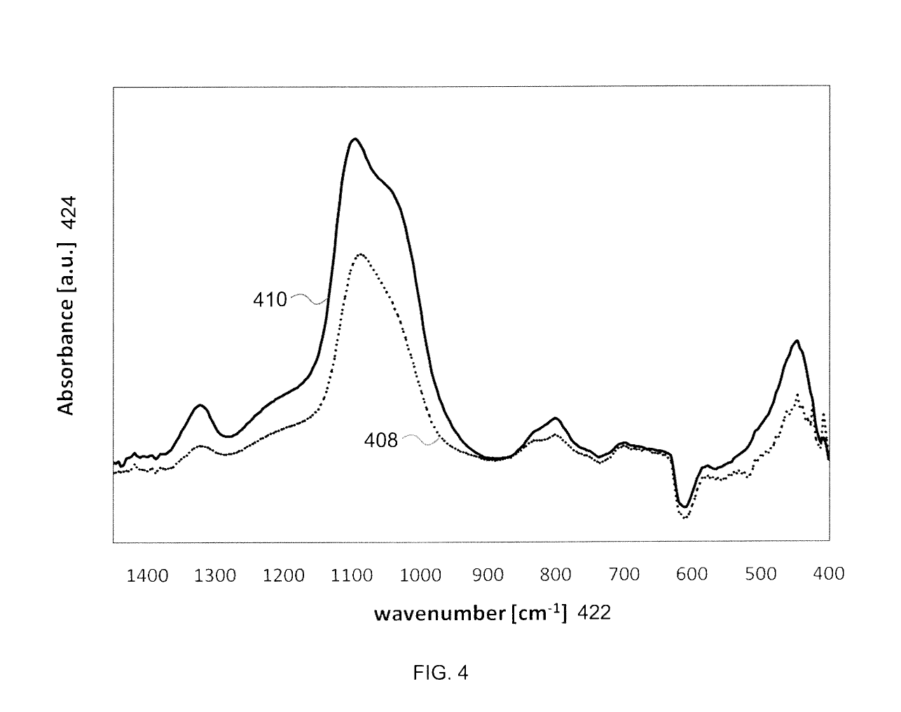

Referring now to FIG. 4, FTIR (Fourier transform spectroscopy) spectra were measured for two double-sided polished mono-crystalline silicon substrates, with a resistivity of about 10,000 Ohm-cm, a first substrate with a porous silicon layer created on one side of the substrate and a substrate without any porous silicon, in accordance with the invention. The first spectrum 408 shows the absorbance of substrate areas without porous silicon, while the second spectrum 410 shows the absorbance of substrate areas with porous silicon.

In general, FTIR (Fourier transform spectroscopy) is a measurement technique whereby spectra are collected based on measurements of the temporal coherence of a radiative source, using time-domain measurements of the electromagnetic radiation or other type of radiation 422 (shown as wave number on the horizontal axis). At certain resonant frequencies characteristic of the chemical bonding within a specific sample, the radiation 422 will be absorbed (shown as absorbance A.U. on the vertical axis 424) resulting in a series of peaks in the spectrum, which can then be used to identify the chemical bonding within samples. The radiation absorption is proportional to the number of bonds absorbing at a given frequency.

Here, for the porous silicon substrate, one side of the substrate was covered with a masking wax prior to being immersed in a HF and HNO₃ mixture for 20 minutes in order to create a porous silicon layer on a single substrate surface. The masking wax layer was subsequently removed with acetone followed by a water rinse. The porous silicon and non-porous silicon samples were cleaned using a mixture of hydrofluoric acid (HF) and hydrochloric acid (HCl). The substrates were loaded into a standard tube furnace and subjected to a POCl₃ deposition step at about 800° C. for about 20 minutes, using a nitrogen (carrier N₂) to oxygen (reactive O₂) gas ratio of about 1:1 during deposition. No subsequent drive-in step was performed. The process was thus terminated after PSG deposition onto both substrates.

First spectrum 408 (corresponding to a silicon substrate without porous silicon) and second spectrum 410 (corresponding to a silicon substrate with porous silicon created using a 20 minute etch) show peaks in the range of 1330 cm⁻¹ that is characteristic of P═O (phosphorous oxygen double bonding) and around 450 cm⁻¹, 800 cm⁻¹, and 1100 cm⁻¹ that are characteristic of Si—O (silicon oxygen single bonding), all typical of deposited PSG films. The absorbance of the second spectrum 410 is substantially greater than the absorbance of the first spectrum 408, indicating that there is significantly more PSG embedded in the porous silicon layer compared to a bare silicon substrate.

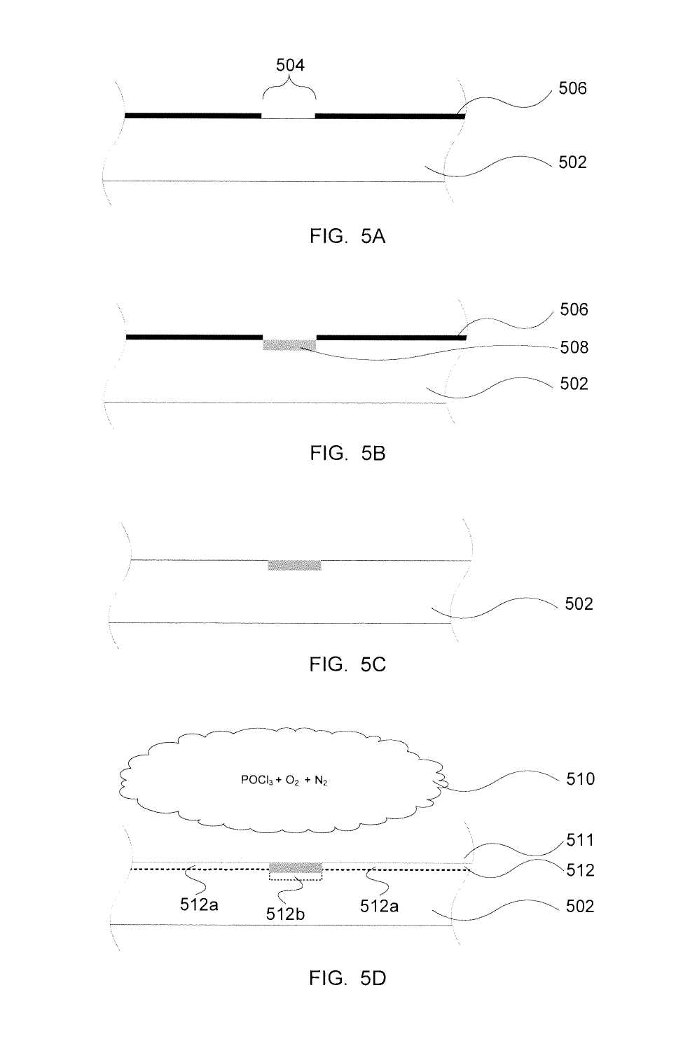

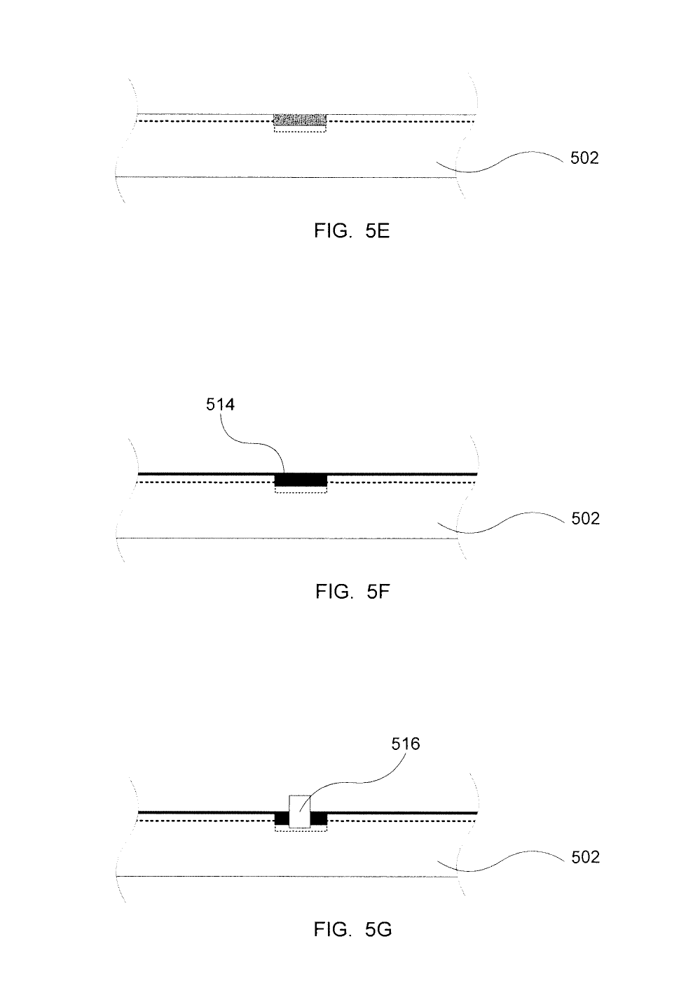

Referring now to FIGS. 5A-G, a simplified set of diagrams showing an optimized method for forming a multi-doped junction on a substrate with porous silicon with a positive pattern mask, in accordance with the invention.

In FIG. 5A, a positive pattern mask 506 (i.e., wax, photoresist, etc.) is deposited on the silicon substrate 502 surface, with exposed areas 504 in the mask corresponding to heavily doped metal contact regions. Methods of depositing the mask include roll coating, slot die coating, gravure printing, flexographic drum printing, and inkjet printing.

In FIG. 5B, a porous silicon region 508 is created via exposure to a set of etchants (i.e., HF and HNO₃ mixture, etc.) for an etch time period. In general, a greater etch time period corresponds to greater porosity.

In FIG. 5C, positive pattern mask 506 of FIG. 5B is removed with appropriate mask removal chemicals, such as acetone or appropriate removal techniques such as using a hot-air knife.

In FIG. 5D, doped silicon substrate 502 is positioned in a furnace (e.g. quartz tube furnace, belt furnace etc) and the dopant diffusion step is started. Silicon substrate 502 is loaded into a diffusion furnace and heated to a diffusion temperature (preferably between about 725° C. and about 850° C. and between 10 and 35 minutes, more preferably between about 750° C. and about 825° C. and between 15 and 30 minutes, and most preferably about 800° C. and for about 20 minutes.) During which time, nitrogen is flowed as a carrier gas through a bubbler filled with a low concentration liquid POCl₃ (phosphorus oxychloride), O₂ gas, and N₂ gas to form a processing gas 510. During the thermal process, O₂ molecules react with POCl₃ molecules to form PSG (phosphosilicate glass) layer 511 comprising P₂O₅ (phosphorus pentoxide), on doped silicon substrate 502. Cl₂ gas, produced as a byproduct, interacts with and removes metal impurities in doped silicon substrate 502. As the chemical process continues, phosphorus diffuses into the silicon wafer to form heavily (n-type) doped emitter region 512b underneath porous silicon region 508, and lightly (n-type) doped emitter region 512a elsewhere on the front surface of doped silicon substrate 502.

In FIG. 5E, PSG layer 511 of FIG. 5D is removed from doped silicon substrate 502 using a batch HF wet bench or other suitable means.

In FIG. 5F, SiNx 514 is deposited on the surface of doped silicon substrate 502.

In FIG. 5G, the front metal contact 516 is deposited.

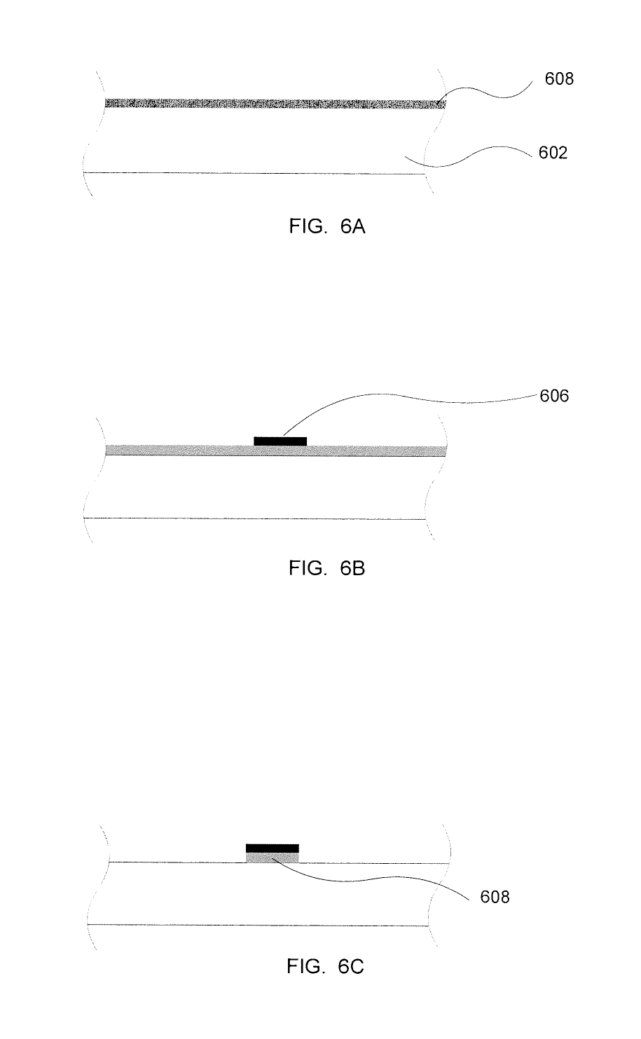

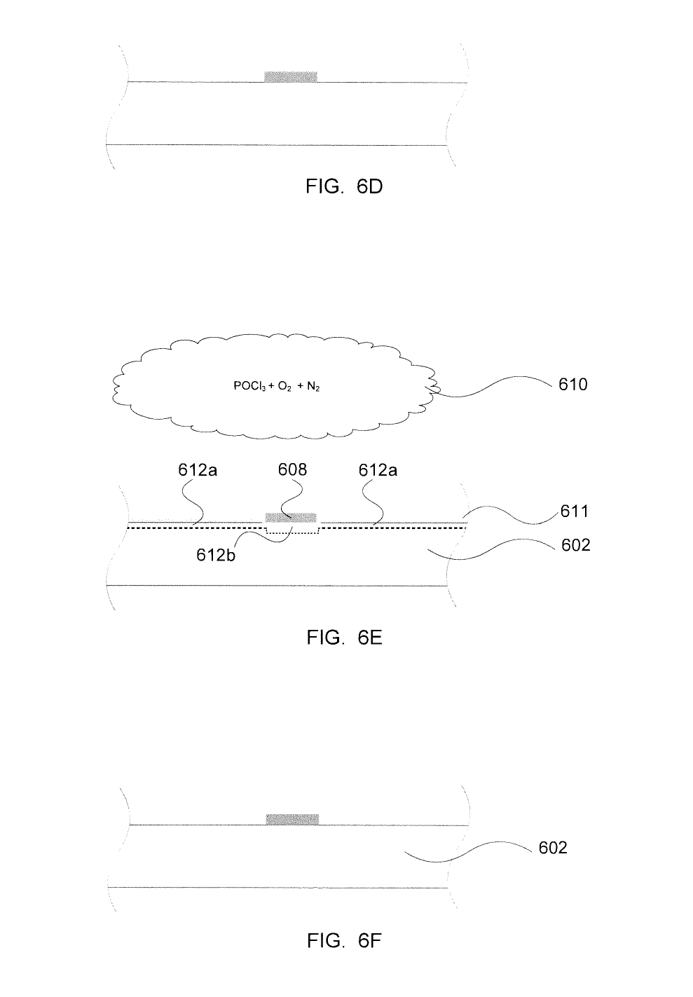

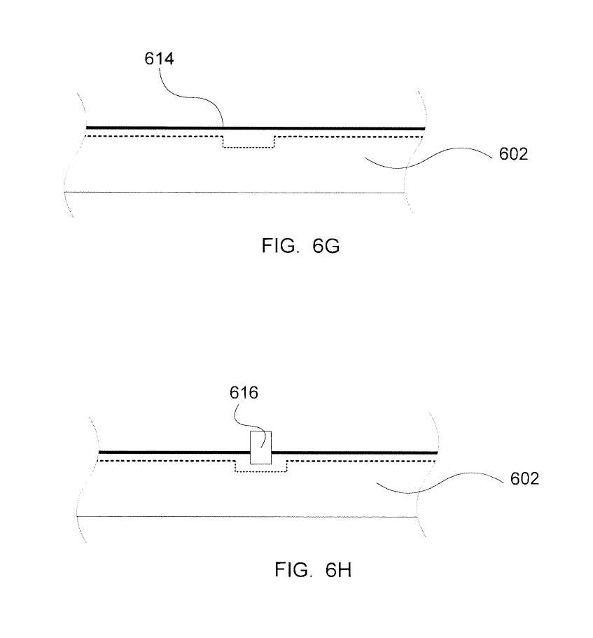

Referring now to FIGS. 6A-H, a simplified set of diagrams showing an optimized method for forming a multi-doped junction on a substrate with porous silicon with a negative pattern mask, in accordance with the invention.

In FIG. 6A, porous silicon region 608 is created on the surface of doped silicon substrate 602 via exposure to a set of etchants (i.e., HF and HNO₃ mixture, etc.) for an etch time period. In general, a greater etch time period corresponds to greater porosity.

In FIG. 6B, a negative pattern mask 606 (i.e., wax, photoresist, etc.) is deposited on the silicon substrate 602 surface, with surface areas covered by negative pattern mask 606 corresponding to heavily doped metal contact regions. Methods of depositing the mask include roll coating, slot die coating, gravure printing, flexographic drum printing, and inkjet printing.

In FIG. 6C, exposed areas of porous silicon region 608 are removed by exposure to a set of etchants (i.e., KOH and water mixture, HNO₃ and water mixture, etc.) for an etch time period.

In FIG. 6D, negative pattern mask 606 of FIG. 6B is removed with appropriate mask removal chemicals, such as acetone or appropriate removal techniques such as using a hot-air knife.

In FIG. 6E, doped silicon substrate 602 is positioned in a furnace (e.g. quartz tube furnace, belt furnace etc) and the dopant diffusion step is started. Doped silicon substrate 602 is loaded into a diffusion furnace and heated to a diffusion temperature (preferably between about 725° C. and about 850° C. and between 10 and 35 minutes, more preferably between about 750° C. and about 825° C. and between 15 and 30 minutes, and most preferably about 800° C. and for about 20 minutes.) During which time, nitrogen is flowed as a carrier gas through a bubbler filled with a low concentration liquid POCl₃ (phosphorus oxychloride), O₂ gas, and N₂ gas to form a processing gas 610. During the thermal process, O₂ molecules react with POCl₃ molecules to form PSG (phosphosilicate glass) layer 611 comprising P₂O₅ (phosphorus pentoxide), on doped silicon substrate 602. Cl₂ gas, produced as a byproduct, interacts with and removes metal impurities in doped silicon substrate 602. As the chemical process continues, phosphorus diffuses into the silicon wafer to form heavily (n-type) doped emitter region 612b underneath porous silicon region 608, and lightly (n-type) doped emitter region 612a elsewhere on the front surface of doped silicon substrate 602.

In FIG. 6F, PSG layer 611 of FIG. 6E is removed from doped silicon substrate 602 using a batch HF wet bench or other suitable means.

In FIG. 6G, SiNx 614 is deposited on the surface of doped silicon substrate 602.

In FIG. 6H, the front metal contact 616 is deposited.

The inventions illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed.

Thus, it should be understood that although the present invention has been specifically disclosed by preferred embodiments and optional features, modification, improvement and variation of the inventions herein disclosed may be resorted to by those skilled in the art, and that such modifications, improvements and variations are considered to be within the scope of this invention. The materials, methods, and examples provided here are representative of preferred embodiments, are exemplary, and are not intended as limitations on the scope of the invention.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. In addition, the terms “dopant or doped” and “counter-dopant or counter-doped” refer to a set of dopants of opposite types. That is, if the dopant is p-type, then the counter-dopant is n-type. Furthermore, unless otherwise dopant-types may be switched. In addition, the silicon substrate may be either mono-crystalline or multi-crystalline.

All publications, patent applications, issued patents, and other documents referred to in this specification are herein incorporated by reference as if each individual publication, patent application, issued patent, or other document were specifically and individually indicated to be incorporated by reference in its entirety. Definitions that are contained in text incorporated by reference are excluded to the extent that they contradict definitions in this disclosure.

For the purposes of this disclosure and unless otherwise specified, “a” or “an” means “one or more.” All patents, applications, references and publications cited herein are incorporated by reference in their entirety to the same extent as if they were individually incorporated by reference. In addition, the word set refers to a collection of one or more items or objects.

Advantages of the invention include the production of low cost and efficient junctions for electrical devices, such as solar cells.

Having disclosed exemplary embodiments and the best mode, modifications and variations may be made to the disclosed embodiments while remaining within the subject and spirit of the invention as defined by the following claims.

What is claimed is:

1. A method of forming a multi-doped junction on a substrate, comprising:
providing the substrate doped with boron atoms, the substrate comprising a front crystalline substrate surface;
forming a mask on the front crystalline substrate surface, the mask comprising exposed mask areas and non-exposed mask areas;
exposing the mask to an etchant, wherein porous silicon is formed on the front crystalline substrate surface defined by the exposed mask areas;
removing the mask;
exposing the substrate to a dopant source in a diffusion furnace with a deposition ambient, the deposition ambient comprising POCl₃ gas, at a first temperature and for a first time period, wherein a PSG layer is formed on the front substrate surface; and
heating the substrate in a drive-in ambient to a second temperature and for a second time period;
wherein a first diffused region with a first sheet resistance is formed under the porous silicon, and a second diffused region with a second sheet resistance is formed under the front crystalline substrate surface without the porous silicon, and wherein the first sheet resistance is substantially smaller than the second sheet resistance.

2. The method of claim 1, wherein a ratio of the carrier N₂ gas to the reactive O₂ gas is between about 1:1 to about 1.5:1, the first temperature is between about 700° C. and about 1000° C., and the first time period of about 5 minutes and about 35 minutes.

3. The method of claim 1, wherein the first temperature is between about 725° C. and about 850° C., and the first time period is between about 10 minutes and about 35 minutes.

4. The method of claim 1, wherein the first temperature is between about 750° C. and about 825° C., and the first time period is between about 15 minutes and about 30 minutes.

5. The method of claim 1, wherein the first temperature is about 800° C. and the first time period is about 20 minutes.

6. The method of claim 1, wherein the second temperature is between about 850° C. and about 1050° C. and the second time period is between about 10 minutes and about 60 minutes.

7. The method of claim 1, wherein the second temperature is between about 860° C. and about 950° C. and the second time period is between about 15 minutes and about 30 minutes.

8. The method of claim 1, wherein the second temperature is about 875° C. and the second time period is about 25 minutes.

9. A method of forming a multi-doped junction on a substrate, comprising:
providing the substrate doped with boron atoms, the substrate comprising a front crystalline substrate surface;
exposing the mask to an etchant, wherein porous silicon is formed on the a front crystalline substrate surface;
forming a mask on the front crystalline substrate surface, the mask comprising exposed mask areas and non-exposed mask areas;
exposing the mask to an etchant, wherein the porous silicon is removed from the front crystalline substrate surface defined by the exposed mask areas;
removing the mask;
exposing the substrate to a dopant source in a diffusion furnace with a deposition ambient, the deposition ambient comprising POCl₃ gas, at a first temperature and for a first time period, wherein a PSG layer is formed on the front substrate surface; and
heating the substrate in a drive-in ambient to a second temperature and for a second time period;
wherein a first diffused region with a first sheet resistance is formed under the porous silicon, and a second diffused region with a second sheet resistance is formed under the front crystalline substrate surface without the porous silicon, and wherein the first sheet resistance is substantially smaller than the second sheet resistance.

10. The method of claim 9, wherein a ratio of the carrier N₂ gas to the reactive O₂ gas is between about 1:1 to about 1.5:1, the first temperature is between about 700° C. and about 1000° C., and the first time period of about 5 minutes and about 35 minutes.

11. The method of claim 9, wherein the first temperature is between about 725° C. and about 850° C., and the first time period is between about 10 minutes and about 35 minutes.

12. The method of claim 9, wherein the first temperature is between about 750° C. and about 825° C., and the first time period is between about 15 minutes and about 30 minutes.

13. The method of claim 9, wherein the first temperature is about 800° C. and the first time period is about 20 minutes.

14. The method of claim 9, wherein the second temperature is between about 850° C. and about 1050° C. and the second time period is between about 10 minutes and about 60 minutes.

15. The method of claim 9, wherein the second temperature is between about 860° C. and about 950° C. and the second time period is between about 15 minutes and about 30 minutes.

16. The method of claim 9, wherein the second temperature is about 875° C. and the second time period is about 25 minutes.

17. A method of forming a multi-doped junction on a substrate, comprising:
providing the substrate doped with boron atoms, the substrate comprising a front crystalline substrate surface;
forming a mask on the front crystalline substrate surface, the mask comprising exposed mask areas and non-exposed mask areas;
exposing the mask to an etchant, wherein porous silicon is formed on the front crystalline substrate surface defined by the exposed mask areas;
removing the mask;
exposing the substrate to a dopant source in a diffusion furnace with a deposition ambient, the deposition ambient comprising phosphorous, at a first temperature and for a first time period, wherein a PSG layer is formed on the front substrate surface; and
heating the substrate in a drive-in ambient to a second temperature and for a second time period;
wherein a first diffused region with a first sheet resistance is formed under the porous silicon, and a second diffused region with a second sheet resistance is formed under the front crystalline substrate surface without the porous silicon, and wherein the first sheet resistance is substantially smaller than the second sheet resistance.

18. A method of forming a multi-doped junction on a substrate, comprising:
providing the substrate doped with phosphorous atoms, the substrate comprising a front crystalline substrate surface;
forming a mask on the front crystalline substrate surface, the mask comprising exposed mask areas and non-exposed mask areas;
exposing the mask to an etchant, wherein porous silicon is formed on the front crystalline substrate surface defined by the exposed mask areas;
removing the mask;
exposing the substrate to a dopant source in a diffusion furnace with a deposition ambient, the deposition ambient comprising boron at a first temperature and for a first time period, wherein a BSG layer is formed on the front substrate surface; and
heating the substrate in a drive-in ambient to a second temperature and for a second time period;
wherein a first diffused region with a first sheet resistance is formed under the porous silicon, and a second diffused region with a second sheet resistance is formed under the front crystalline substrate surface without the porous silicon, and wherein the first sheet resistance is substantially smaller than the second sheet resistance.

19. A method of forming a multi-doped junction on a substrate, comprising:
providing the substrate doped with phosphorous atoms, the substrate comprising a front crystalline substrate surface;
exposing the mask to an etchant, wherein porous silicon is formed on the a front crystalline substrate surface;
forming a mask on the front crystalline substrate surface, the mask comprising exposed mask areas and non-exposed mask areas;
exposing the mask to an etchant, wherein the porous silicon is removed from the front crystalline substrate surface defined by the exposed mask areas;
removing the mask;
exposing the substrate to a dopant source in a diffusion furnace with a deposition ambient, the deposition ambient comprising boron at a first temperature and for a first time period, wherein a BSG layer is formed on the front substrate surface; and
heating the substrate in a drive-in ambient to a second temperature and for a second time period;
wherein a first diffused region with a first sheet resistance is formed under the porous silicon, and a second diffused region with a second sheet resistance is formed under the front crystalline substrate surface without the porous silicon, and wherein the first sheet resistance is substantially smaller than the second sheet resistance.
